(19) United States
(12) Patent Application Publication
(10) Pub. No.: US 2018/0329240 A1
(43) Pub. Date: Nov. 15, 2018

(54) SELF-COOLED LASER INTEGRATED DEVICE AND SUBSTRATE ARCHITECTURE

(71) Applicant: Intel Corporation, Santa Clara, CA (US)

(72) Inventors: Vivek RAGHUNATHAN, Mountain View, CA (US); Mihir K. ROY, Chandler, AZ (US); Ravindranath V. MAHAJAN, Chandler, AZ (US)

(21) Appl. No.: 15/774,432

(22) PCT Filed: Dec. 26, 2015
(86) PCT No.: PCT/US2015/000399

§ 371 Date: May 8, 2018

(51) Int. Cl. G02F 1/13357; H05K 1/18; H05K 1/02; H05K 3/30; H01S 3/04

(52) U.S. Cl. CPC G02F 1/1336; H05K 1/181; G02F 2001/133628; H05K 3/303; H01S 3/0408; H05K 1/0203

(57) ABSTRACT

Embodiments are generally directed to a self-cooled laser integrated device and substrate architecture. An embodiment of a device includes a substrate or printed circuit board (PCB); a component coupled with the substrate or PCB, the component including an cooling agent on at least one side of the component; one or more laser sources, at least a first laser source of the one or more laser sources being implemented to direct laser light onto the cooling agent; and a controller to drive the laser source, wherein the cooling agent provides cooling for the component when the laser light is directed on the engineered cooling agent.

### TECHNICAL FIELD

Embodiments described herein generally relate to the field of electronic devices and, more particularly, to a self-cooled laser integrated device and substrate architecture.

### BACKGROUND

As electronic devices, such as mobile devices, become smaller physically while operating at high speeds, the need for effective cooling has grown more important.

This is particularly true in wearable devices because cooling may be required not only to protect the electronics of the device and the data held by such electronics, but further for the comfort of the user as the heat generated by electronics may potentially make wearable device uncomfortable to have near or on the body of the user.

However, the size of wearable devices is contrary to many conventional cooling technologies, as these cooling technologies require a certain amount of physical volume to provide effective cooling.

### BRIEF DESCRIPTION OF THE DRAWINGS

Embodiments described here are illustrated by way of example, and not by way of limitation, in the figures of the accompanying drawings in which like reference numerals refer to similar elements.

FIG. 1 is an illustration of a wearable device including laser cooling according to an embodiment;

FIG. 2 is an illustration of substrate architecture including laser cooling operation according to an embodiment;

FIG. 3 is an illustration of a laser cooled apparatus according to an embodiment;

FIG. 4 is a flowchart to illustrate a process for fabrication of an apparatus with laser cooling according to an embodiment; and

FIG. 5 is an illustration of an embodiment of a mobile device to including laser cooling of elements according to an embodiment.

### DETAILED DESCRIPTION

Embodiments described herein are generally directed to self-cooled laser integrated device and substrate architecture.

For the purposes of this description, the following shall apply:

“Mobile electronic device” or “mobile device” refers to a smartphone, smartwatch, tablet computer, notebook or laptop computer, handheld computer, mobile Internet device, wearable technology, or other mobile electronic device that includes processing capability.

“Wearable electronics” refers to an electronic device that is integrated at least in part into an item that may be worn by a user. Wearable electronics may include electronic devices that operate independently as well as electronic devices that operate in conjunction with a second electronic device, such as a mobile device.

“Laser source” or “laser” refers to a mechanism to produce laser light.

“Optical chip” refers to an electronic device that provides for optical operation in a device, including, but not limited to, a laser mixer.

In some embodiments, an apparatus, system, or method provides a self-cooled laser integrated wearable substrate architecture, wherein the operation of a laser may be utilized for cooling of an electronic device. In some embodiments, substrate architecture leverages one or more surface mounted lasers to cool a chip or die using the anti-Stokes phenomenon, in which anti-Stokes scattering of electromagnetic radiation emission dominates the Stokes emission such that average energy of the photons emitted by a solid is larger than the energy of the ones it absorbs. In some embodiments, a chip or die is a processing component including certain data processing functions.

Energy conversion, while often working contrary to purposes of an electronic device, can work to the benefit of the device operation in terms of cooling provided in the energy conversion process for laser light generation. In some embodiments, this laser cooling effect is applied to provide cooling in an electronic device.

The cooling operation provided by the laser effect may be utilized for multiple advantages. In addition to protecting data of a device and potentially extending the life of the device through the laser cooling, laser cooling may provide a further benefit for the user in, for example, a wearable device because the added comfort for the user, wherein a wearable device can potentially provide enough heat to be uncomfortable for a user. Particular examples of a wearable device include smart watches, bracelets, and phones that require both display controls and computation. In certain implementations, the computation dies in such packages may not require a complex thermal control, and, in some embodiments, one or more embedded/integrated laser sources of the device are applied to cool the die to increase the lifetime of the device, and to enhance ergonomic comfort by reducing the skin/contact temperature when running power intensive applications like projection by providing cooling on demand.

In some embodiments, a laser cooling mechanism is operable to provide cooling at all times when the laser is being utilized for projection, which is generally for display operation. Stated in another way, when a laser is enabled for device operation, the laser cooling is enabled as well. In this manner, the laser cooling is applied when the laser apparatus is needed for light projection, which is also a period of high power demand and heating, and thus is likely when cooling is most needed for the electronic device.

In an operation in which a laser is currently utilized in a device, there is no energy waste in taking advantage of the additional cooling effect of a laser. As the laser is already a part of the device for the light generation, laser cooling leverages the existing function of the laser element in the device without additional energy cost.

In alternative embodiments, an apparatus or system may further include a cooling control to turn laser cooling on as needed, thus operating to direct cooling when a sensor indicates that there is excess heat or when the laser cooling is otherwise enabled. In one example, a cooling control could be switchable by a user input.

In some embodiments, a laser cooling mechanism utilizes a laser in a green wavelength because of current advantages for up-conversion. However, embodiments are not limited to a particular color of laser light, and any wavelength that is both usable for an apparatus and provides sufficient cooling in energy conversion may be applied.

In some embodiments, a laser cooling mechanism may further be utilized in a temperature sensor. In some embodiments, a process may include obtaining temperature for an electronic device, wherein such information may be used for temperature mapping of the core.

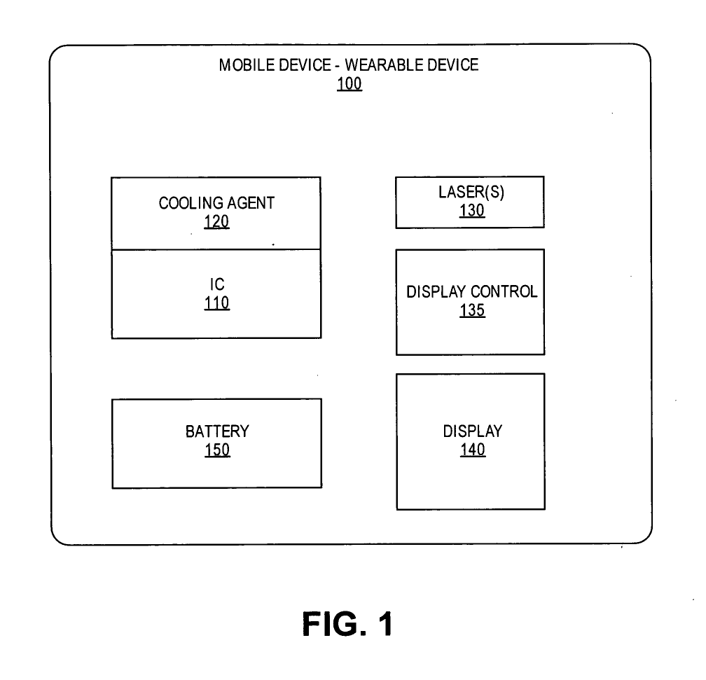

FIG. 1 is an illustration of a wearable device including laser cooling according to an embodiment. In some embodiments, a mobile device may specifically be a wearable device 100. The wearable device 100 includes an integrated circuit IC) 110 with a cooling agent 120, wherein the cooling agent is chosen to respond to laser light in a manner to provide cooling using the anti-Stokes phenomenon.

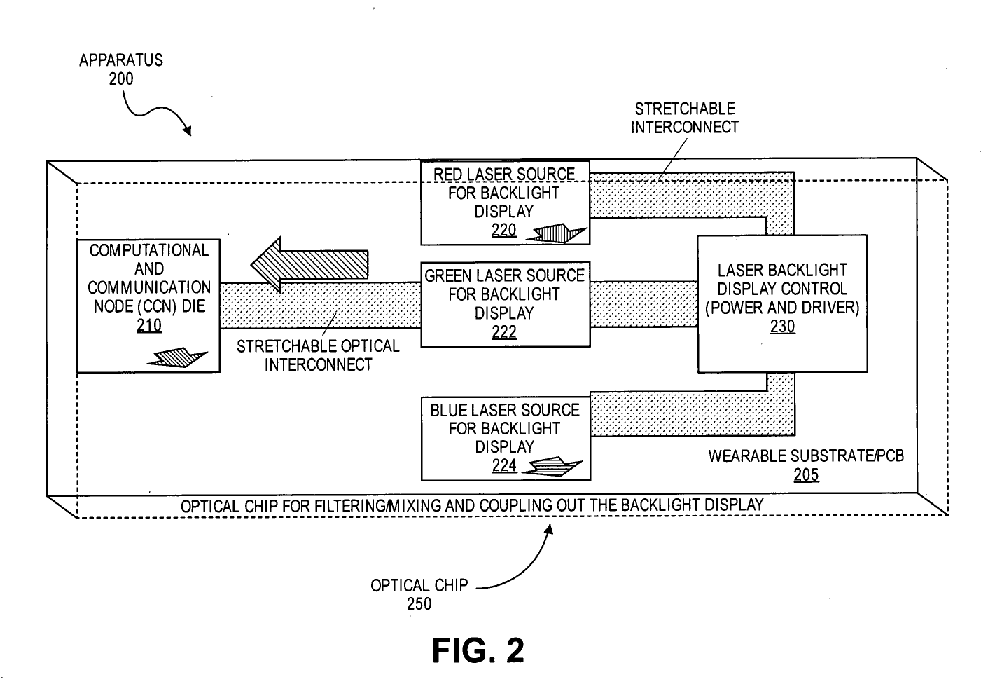

In some embodiments, the cooling apparatus includes one or more lasers 130 to provide cooling operation. In some embodiments, the wearable device 100 further includes a display control 135, which may provide control operations for the laser 130, and a display 140, such as a LCD (liquid crystal display). In some embodiments, the laser 130 operates at least in part in connection with the operation of the display 140, such as in providing backlight operation. In some embodiments, the wearable device 100 may further include a battery 150 or other energy source to supply power for the wearable device 100. The elements of FIG. 1 are further illustrated in FIGS. 2, 3, and 5.

While FIG. 1 applies the particular example of a wearable device, the laser cooling operation can be utilized with any apparatus or system including a display for which laser light projection is utilized, including larger devices such as laptop computers.

FIG. 2 is an illustration of substrate architecture including laser cooling operation according to an embodiment. In some embodiments, an apparatus 200 includes a wearable printed circuit board (PCB)/substrate 205 architecture, wherein a computation/communication node (CCN) die 210 (or other processing component), surface mounted laser sources (for backlight display) (red laser source 220, green laser source 222, and blue laser source 224), and a backlight display control node (providing power and driver for the laser source) 230 are installed (such as, for example, being flip chip bonded or mounted) on a same layer. A CCN die is an element that does not require extensive computation capability, and thus the thermal management of such a die can be reasonably managed with laser cooling operation.

In some embodiments, the laser backlight control node is connected electrically to each of the red laser source 220, green laser source 222, and blue laser source 224, where the interconnect may include, but is not limited to, a stretchable interconnect to provide connection on a wearable substrate or PCB that may be flexible. Further, the green laser source 222 is connected optically with the CCN die 210 to provide laser cooling operation, wherein the optical interconnect may include, but is not limited to, a stretchable optical interconnect.

In some embodiments, an optical chip 250 is bonded/integrated to this underlying layer. In some embodiments, the optical chip includes, but is not limited to, optical components (filters, acousto-optic modulators (AOMs)/couplers, and other elements) required to couple out light from the underlying laser sources 220-240 and mix the light (RGB—red, green, blue) in a manner that is governed by the laser backlight display controller 230 to provide a final output. In some embodiments, the laser backlight display controller 230 is to power and drive the lasers 220-224 and other active optical devices in the optical chip 250.

In some embodiments, the apparatus 200 uses the laser light produces by the green laser 222 to cool the CCN die 210, and the green light is then coupled out from the CCN die 210. However, in other embodiments a different laser source or a combination of laser sources may be implemented to cool the CCN die 210. In some embodiments, the optical chip 250 serves to filter and separate out the non-converted green light and anti-stokes shifted light for purposes of supporting a display operation. In some embodiments, the optical chip may further act as a laser source, and an additional electronic chip is used to modulate performance of the optical chip.

Laser cooling as a consequence of Anti-Stokes shift has been documented and demonstrated. In an example, yttrium oxysulfide doped with gadolinium oxysulfide is an industrial anti-Stokes pigment that absorbs in the near-infrared and emits in the visible portion of the spectrum. In solid state materials, laser cooling is achieved by annihilation of phonons (quanta of lattice vibrations) during Anti-Stokes luminescence.

In some embodiments, a back side of the CCN die 210 is engineered such that yttrium doped glasses act as a thermal interface material. In direct bandgap semiconductors, laser cooling is attributed to exciton-longitudinal optical phonon (exciton-LOP) coupling. II-VI direct bandgap materials, like CdS (cadmium sulfide), exhibit strong exciton-LOP coupling and have been leveraged to demonstrate cooling up to 40 K at by pumping laser between 500-532 nm.

In some embodiments, CdS is applied as an interfacial “engineered cooling agent”, as the on substrate green laser is utilized for cooling. In addition, CdS can serve as a semiconductor interface between the CCN die and the optical chip. In an alternative embodiment, the II-VI platform may be used to build both the CCN die and the optical chip, and the interface is cooled using the green laser.

With regard to power requirements, a diode pumped micro-laser power traditionally used for backlit displays is typically of the order of 0.5-1.0 Watts. In contrast, cooling of CdS has been demonstrated with laser powers of less than 12 mW (milliwatts). In other words, only a fraction of laser power needed for backlight displays is required for cooling function.

In some embodiments, cooling may be directed to areas requiring the greatest amount of cooling. In some embodiments, laser light, such as a green laser light, may be concentrated on hot spots of a die, such as by using DLP (digital light processing) mirror technology.

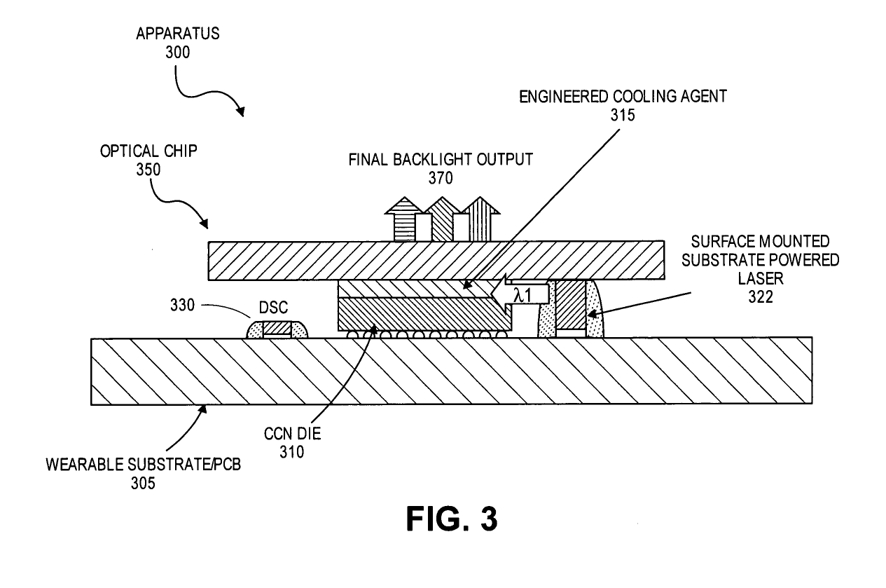

FIG. 3 is an illustration of a laser cooled apparatus according to an embodiment. As illustrated in FIG. 3, in an example an apparatus 300 may include a wearable substrate or printed circuit board (PCB) (i.e., a substrate or PCB for devices including wearable device) 305. However, embodiments are not limited to a particular device, and may include any electronic device having laser capability and requiring cooling operation. As provided in FIG. 3, the apparatus 300 may include a CCN die 310 or other processing component, a surface mounted substrate powered laser (or lasers) 322, and a DSC (digital signal controller) for signal control, such elements being coupled with the substrate 300.

In some embodiments, an engineered cooling agent 315, including, but not limited to, a CdS surface, is fabricated on a back side of the CCN die 310. In some embodiments, the surface mounted laser 322 is installed to direct at least a portion of the generated laser light, such as green laser light in this example, onto the engineered cooling agent 315. In some embodiments, the light is directed onto such engineered cooling agent 315 at any time the surface mounted laser 322 is active. In an alternative embodiment, the apparatus 300 may include a cooling control to enable or disable the laser cooling operation.

In some embodiments, an optical chip 350 is mounted above the CCN die 310. In some embodiments, optical chip 350 is to provide control of output for a display backlight, the optical chip 350 to receive the laser light produced by the laser operation and process such light output to produce a final backlight output 370. In some embodiments, the wavelength applied for cooling is up-converted before processing by the optical chip 350, wherein processing may include optical coupling, filtering, modulating, and mixing.

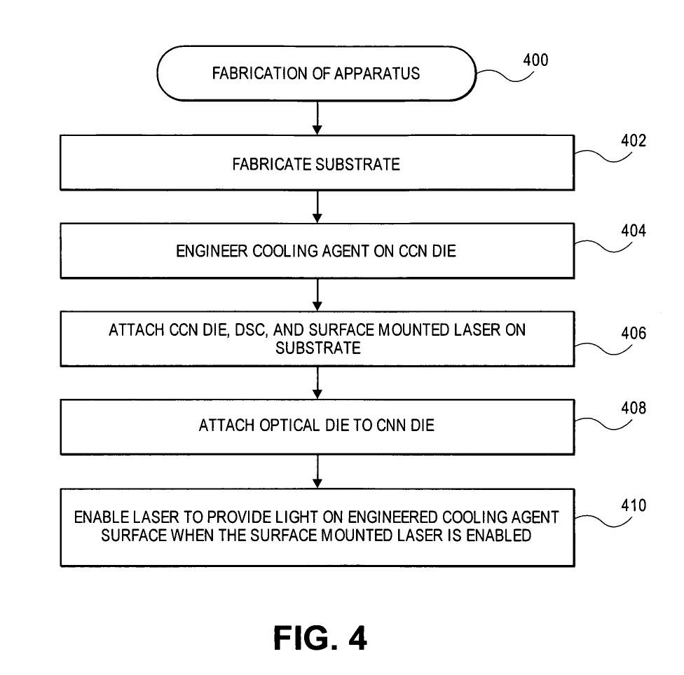

FIG. 4 is a flowchart to illustrate a process for fabrication of an apparatus with laser cooling according to an embodiment. In some embodiments, a process for fabrication of an apparatus 400 includes fabrication of a substrate or PCB. In some embodiments, the substrate or die may include a wearable substrate or die for use in a wearable device.

In some embodiments, the process further includes engineering of a cooling agent on a device, wherein the device may include a processing component such as a CCN die 404, and wherein the engineering of the cooling agent includes generating a surface that operates in response to laser light, such as laser light at a particular frequency range, to provide a cooling effect.

In some embodiments, the process further includes attaching the CCN die, together with a DSC and surface mounted laser, onto the substrate or PCB 406. In some embodiments, the process further includes attaching an optical die onto the CCN die 408, and wherein the installation includes enabling the laser to provide laser light onto the engineered cooling agent when the surface mounted laser is enabled 410.

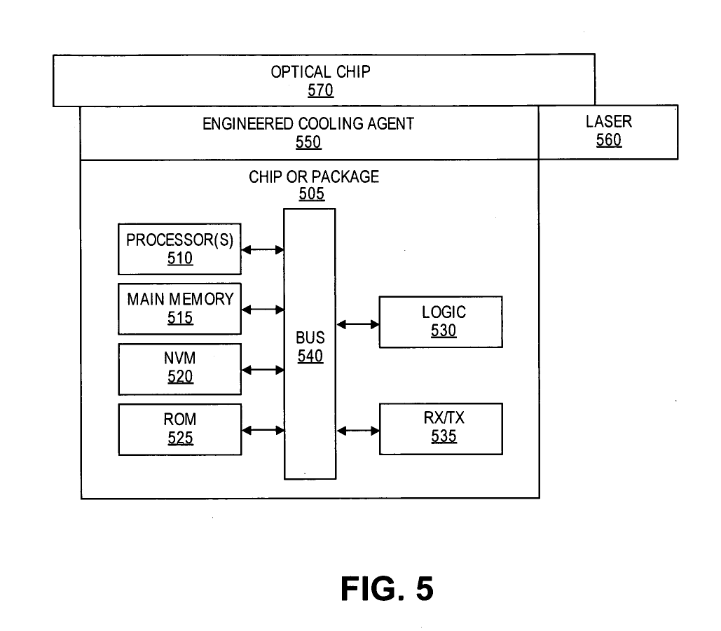

FIG. 5 is an illustration of an embodiment of a mobile device to including laser cooling of elements according to an embodiment. In this illustration, certain standard and well-known components that are not germane to the present description are not shown. Elements shown as separate elements may be combined, including, for example, an SoC (System on Chip) or SiP (System in Package) combining multiple elements on a single chip or package.

In some embodiments, a mobile device 500 includes a chip or package 505 to provide computational and other functions; an engineered cooling agent 550 to provide cooling for the chip or package 505; a laser 560 to provide laser light directed onto to engineering cooling agent 550; and an optical chip 570 to provide optical processing. The chip or package 505 may include, but is not limited to, a computation/communication node (CCN) die.

In some embodiments, the chip or package 505 includes processing capability or means, such as one or more processors or controllers 510 coupled to one or more buses or interconnects, shown in general as bus 540. In some embodiments, the processors may include one or more general-purpose processors or special-processor processors. The bus 540 is a communication means for transmission of data. The bus 540 is illustrated as a single bus for simplicity, but may represent multiple different interconnects or buses and the component connections to such interconnects or buses may vary.

The chip or package 505 may include one or more of the following in certain implementations:

In some embodiments, the chip or package 505 further comprises a random access memory (RAM) or other dynamic storage device or element as a main memory 515 for storing information and instructions to be executed by the processor 510. Main memory 515 may include, but is not limited to, dynamic random access memory (DRAM). The chip or package 505 also may comprise a non-volatile memory (NVM) 520; and a read only memory (ROM) 520 or other static storage device for storing static information and instructions for the processor 510.

In some embodiments, the chip or package 505 includes special purpose logic 530 relating to the operation of the mobile device, and one or more transmitters or receivers 535 to provide wired or wireless communications. Wireless communication includes, but is not limited to, Wi-Fi, Bluetooth™, near field communication, and other wireless communication standards.

In the description above, for the purposes of explanation, numerous specific details are set forth in order to provide a thorough understanding of the described embodiments. It will be apparent, however, to one skilled in the art that embodiments may be practiced without some of these specific details. In other instances, well-known structures and devices are shown in block diagram form. There may be intermediate structure between illustrated components. The components described or illustrated herein may have additional inputs or outputs that are not illustrated or described.

Various embodiments may include various processes. These processes may be performed by hardware components or may be embodied in computer program or machine-executable instructions, which may be used to cause a general-purpose or special-purpose processor or logic circuits programmed with the instructions to perform the processes. Alternatively, the processes may be performed by a combination of hardware and software.

Portions of various embodiments may be provided as a computer program product, which may include a computer-readable medium having stored thereon computer program instructions, which may be used to program a computer (or other electronic devices) for execution by one or more processors to perform a process according to certain embodiments. The computer-readable medium may include, but is not limited to, magnetic disks, optical disks, compact disk read-only memory (CD-ROM), and magneto-optical disks, read-only memory (ROM), random access memory (RAM), erasable programmable read-only memory (EPROM), electrically-erasable programmable read-only memory (EEPROM), magnetic cards or optical cards, flash memory, or other type of computer-readable medium suitable for storing electronic instructions. Moreover, embodiments may also be downloaded as a computer program product, wherein the program may be transferred from a remote computer to a requesting computer.

Many of the methods are described in their most basic form, but processes can be added to or deleted from any of the methods and information can be added or subtracted from any of the described messages without departing from the basic scope of the present embodiments. It will be apparent to those skilled in the art that many further modifications and adaptations can be made. The particular embodiments are not provided to limit the concept but to illustrate it. The scope of the embodiments is not to be determined by the specific examples provided above but only by the claims below.

If it is said that an element “A” is coupled to or with element “B,” element A may be directly coupled to element B or be indirectly coupled through, for example, element C. When the specification or claims state that a component, feature, structure, process, or characteristic A “causes” a component, feature, structure, process, or characteristic B, it means that “A” is at least a partial cause of “B” but that there may also be at least one other component, feature, structure, process, or characteristic that assists in causing “B.” If the specification indicates that a component, feature, structure, process, or characteristic “may”, “might”, or “could” be included, that particular component, feature, structure, process, or characteristic is not required to be included. If the specification or claim refers to “a” or “an” element, this does not mean there is only one of the described elements.

An embodiment is an implementation or example. Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. It should be appreciated that in the foregoing description of exemplary embodiments, various features are sometimes grouped together in a single embodiment, figure, or description thereof for the purpose of streamlining the disclosure and aiding in the understanding of one or more of the various novel aspects. This method of disclosure, however, is not to be interpreted as reflecting an intention that the claimed embodiments requires more features than are expressly recited in each claim. Rather, as the following claims reflect, novel aspects lie in less than all features of a single foregoing disclosed embodiment. Thus, the claims are hereby expressly incorporated into this description, with each claim standing on its own as a separate embodiment.

In some embodiments, a device includes a substrate or printed circuit board (PCB); a component coupled with the substrate or PCB, the component including a cooling agent on at least one side of the component; one or more laser sources, at least a first laser source of the one or more laser sources being implemented to direct laser light onto the cooling agent; and a controller to drive the laser source. In some embodiments, the cooling agent provides cooling for the component when the laser light is directed on the engineered cooling agent.

In some embodiments, the device further includes an optical chip, the optical chip being coupled with the component, the optical chip to process laser light generated by the one or more laser sources.

In some embodiments, the first laser source is to direct laser light onto the engineered cooling agent when the first laser source is enabled.

In some embodiments, the cooling agent provides cooling in response to the anti-Stokes phenomenon.

In some embodiments, the cooling agent includes CdS (cadmium sulfide) applied as an engineered cooling agent.

In some embodiments, the first laser source is to provide light in a green frequency.

In some embodiments, the device is a wearable device.

In some embodiments, the component is a computation/communication node (CCN) die.

In some embodiments, wherein the one or more laser sources are to provide laser light to illuminate a backlight of a liquid crystal display (LCD).

In some embodiments, a method includes forming a cooling agent on a die, wherein the die includes a processing capability; coupling the die to a substrate; and coupling at least a first surface mounted laser and a laser controller on the substrate. In some embodiments, the first surface mounted laser is installed to direct laser light onto the cooling agent of the die to provide cooling for the die.

In some embodiments, the first surface mounted laser is installed to direct the laser light onto the cooling agent at any time the first surface mounted laser is enabled.

In some embodiments, the method further include installing an optical chip on the die, the optical chip being installed to receive and process laser light from one or more laser sources including the first surface mounted laser.

In some embodiments, forming the cooling agent is to include applying CdS (cadmium sulfide) as an engineered cooling agent.

In some embodiments, the first laser source is to provide laser light in a green frequency.

In some embodiments, a mobile device includes a liquid crystal display (LCD) screen including a backlight; one or more surface mounted lasers to provide laser light to illuminate the backlight of the LCD screen; a display controller to control the one or more surface mounted lasers; a processing element, the processing element including a cooling agent on at least one side of the processing element; and an interconnect to direct laser light from at least a first laser source of the one or more surface mounted lasers onto the cooling agent of the processing component. In some embodiments, the cooling agent provides cooling for the processing component when the laser light is directed on the cooling agent.

In some embodiments, the mobile device further includes an optical chip, the optical chip being coupled with the component, the optical chip to process laser light generated by the one or more surface mounted laser sources.

In some embodiments, the optical chip is to further operate as a laser source and an electronic chip is to modulate performance of the optical chip.

In some embodiments, the first laser source is to direct laser light onto the engineered cooling agent at any time the first laser source is enabled.

In some embodiments, the cooling agent provides cooling in response to the anti-Stokes phenomenon.

In some embodiments, the cooling agent includes CdS (cadmium sulfide) applied as an engineered cooling agent.

In some embodiments, the first laser source is to provide light in a green wavelength.

In some embodiments, the processing component is a computation/communication node (CCN) die.

In some embodiments, a method to cool a die in a mobile device includes enabling a laser source for a device; directing laser light produced by the laser source onto a cooling agent of the die; and producing a cooling effect for the die in response to the laser light, wherein the cooling effect utilizes the anti-Stokes phenomenon to provide cooling.

What is claimed is:

1. A device comprising:
a substrate or printed circuit board (PCB);
a component coupled with the substrate or PCB, the component including a cooling agent on at least one side of the component;
one or more laser sources, at least a first laser source of the one or more laser sources being implemented to direct laser light onto the cooling agent; and
a controller to drive the laser source;
wherein the cooling agent provides cooling for the component when the laser light is directed on the engineered cooling agent.

2. The device of claim 1, further comprising an optical chip, the optical chip being coupled with the component, the optical chip to process laser light generated by the one or more laser sources.

3. The device of claim 1, wherein the first laser source is to direct laser light onto the engineered cooling agent when the first laser source is enabled.

4. The device of claim 1, wherein the cooling agent provides cooling in response to the anti-Stokes phenomenon.

5. The device of claim 1, wherein the cooling agent includes CdS (cadmium sulfide) applied as an engineered cooling agent.

6. The device of claim 1, wherein the first laser source is to provide light in a green frequency.

7. The device of claim 1, wherein the device is a wearable device.

8. The device of claim 1, wherein the component is a computation/communication node (CCN) die.

9. A method comprising:
forming a cooling agent on a die, wherein the die includes a processing capability;
coupling the die to a substrate; and
coupling at least a first surface mounted laser and a laser controller on the substrate;
wherein the first surface mounted laser is installed to direct laser light onto the cooling agent of the die to provide cooling for the die.

10. The method of claim 9, wherein the first surface mounted laser is installed to direct the laser light onto the cooling agent at any time the first surface mounted laser is enabled.

11. The method of claim 9, further comprising installing an optical chip on the die, the optical chip being installed to receive and process laser light from one or more laser sources including the first surface mounted laser.

12. The method of claim 9, wherein forming the cooling agent is to include applying CdS (cadmium sulfide) as an engineered cooling agent.

13. The method of claim 9, wherein the first laser source is to provide laser light in a green frequency.

14. A mobile device comprising:
a liquid crystal display (LCD) screen including a backlight;
one or more surface mounted lasers to provide laser light to illuminate the backlight of the LCD screen;
a display controller to control the one or more surface mounted lasers;
a processing element, the processing element including a cooling agent on at least one side of the processing element; and
an interconnect to direct laser light from at least a first laser source of the one or more surface mounted lasers onto the cooling agent of the processing component;
wherein the cooling agent provides cooling for the processing component when the laser light is directed onto the cooling agent.

15. The mobile device of claim 14, further comprising an optical chip, the optical chip being coupled with the component, the optical chip to process laser light generated by the one or more surface mounted laser sources.

16. The mobile device of claim 14, wherein the first laser source is to direct laser light onto the engineered cooling agent at any time the first laser source is enabled.

17. The mobile device of claim 14, wherein the cooling agent provides cooling in response to the anti-Stokes phenomenon.

18. The mobile device of claim 14, wherein the cooling agent includes CdS (cadmium sulfide) applied as an engineered cooling agent.

19. The mobile device of claim 14, wherein the first laser source is to provide light in a green wavelength.

20. The mobile device of claim 14, wherein the processing component is a computation/communication node (CCN) die.
